(19) United States
(12) Patent Application Publication
(10) Pub. No.: US 2026/0369336 A1
(43) Pub. Date: Nov. 19, 2026

(54) RANDOM DATA DUPLICATION AND PROGRAM VERIFY SKIP DURING DATA CYCLING AND PADDING

(71) Applicant: Micron Technology, Inc., Boise, ID (US)

(72) Inventors: Chong Giap Chiew, San Jose, CA (US); Tawalin Opastrakoon, Boise, ID (US); Sean Brasfield, Boise, ID (US); Zhi Yin Chiew, Singapore (SG)

(21) Appl. No.: 19/212,083

(22) Filed: May 19, 2025

(51) Int. Cl. G11C 16/34; G11C 16/08; G11C 16/10

(52) U.S. Cl. CPC G11C 16/3495; G11C 16/08; G11C 16/102; G11C 16/3459

(57) ABSTRACT

A system includes a memory device with a memory array. A processing device is coupled to the memory device. The processing device receives an address identifying a portion of the memory array and produces a truncated address by truncating a predefined one or more bits from the address, wherein the truncated address identifies a plurality of sub-portions of the portion of the memory array. The processing device loads a data pattern into a page buffer of the memory device for a first sub-portion of the plurality of sub-portions. The processing device causes the memory device to load the data pattern into the page buffer for each additional sub-portion of the plurality of sub-portions. The processing device causes the memory device to program the data pattern from the page buffer into the first sub-portion and into each additional sub-portion of the plurality of sub-portions of the memory array.

### TECHNICAL FIELD

Embodiments of the disclosure are generally related to memory sub-systems, and more specifically, relate to random data duplication and program verify skip during data cycling and padding.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of some embodiments of the disclosure.

FIG. 1A illustrates an example computing system that includes a memory sub-system in accordance with some embodiments.

FIG. 1B is a block diagram of a memory device in communication with a memory sub-system controller of a memory sub-system according to an embodiment.

FIG. 2A-2B are schematics of portions of an array of memory cells as could be used in a memory of the type described with reference to FIG. 1B according to an embodiment.

FIG. 3A is a table-based depiction of truncating the most significant bit of addresses of the array of memory cells to provide for more-granular addressing within a portion of the array according to an exemplary embodiment.

FIG. 3B is a block diagram depiction of a page buffer into which is loaded data, which is addressed based on the truncated addressing scheme of FIG. 3A according to some embodiments.

FIG. 4 is a flow diagram of an example method of duplicating a data pattern within a page buffer that is written to sub-portions of the portion of the array of FIG. 3B according to some embodiments.

FIG. 5A is a flow diagram of an example method of cycling or padding data using a pulse count determined from programming a first page of a wordline group (WLG) according to some embodiments.

FIG. 5B is a flow diagram of an example method of cycling or padding data using a pulse count determined from programming the first page of the WLG according to at least some embodiments.

FIG. 6A is a memory array-based depiction of the methods of FIGS. 4-5B performed across multiple WLGs of a first block according to some embodiments.

FIG. 6B is a memory array-based depiction of employing the persistence mode of FIG. 5A across multiple WLGs of a second block according to some embodiments.

FIG. 7A is a flow chart of a method for padding pages of an incompletely programmed block with a random data pattern according to some embodiments.

FIG. 7B is a memory array-based depiction of employing the method of FIG. 7A in padding data after user data partially fills a block according to an exemplary embodiment.

FIG. 8 is a block diagram of an example computer system in which embodiments of the present disclosure can operate.

### DETAILED DESCRIPTION

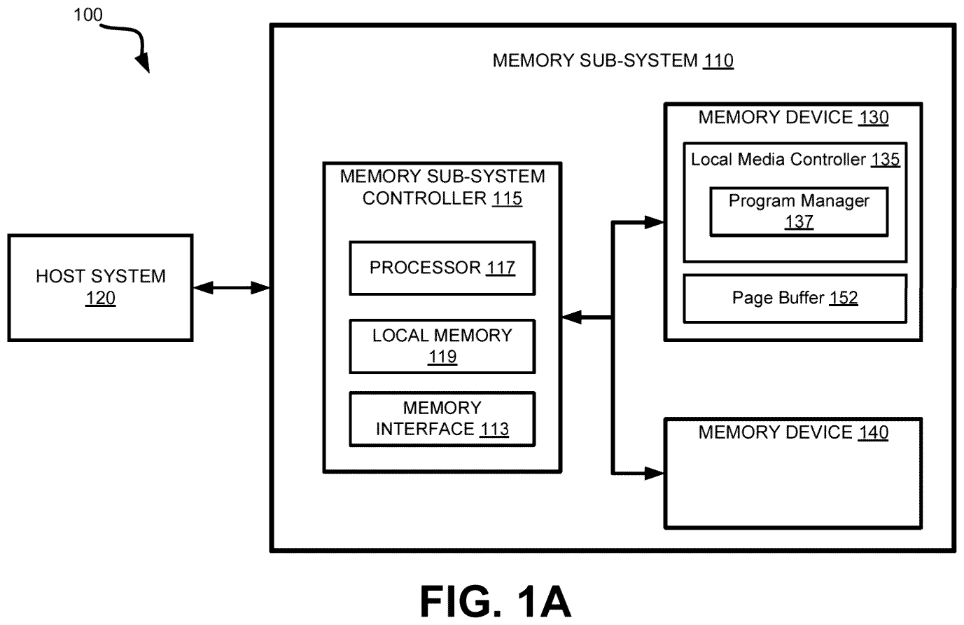

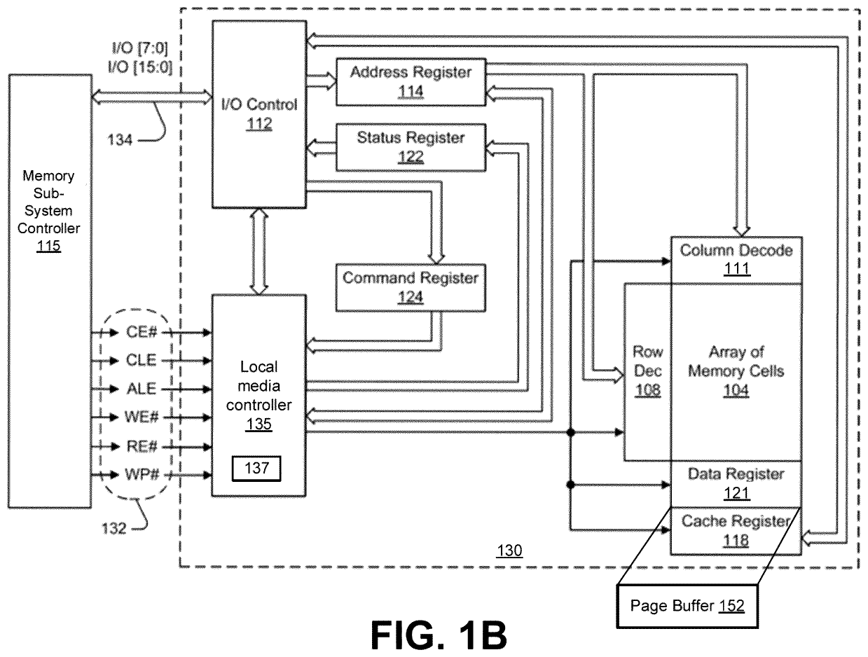

Embodiments of the present disclosure are directed to random data duplication and program verify skip during data cycling and padding. One or more memory devices can be a part of a memory sub-system, which can be a storage device, a memory module, or a hybrid of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a NOT-and (NAND) memory device. Other examples of non-volatile memory devices are described below in conjunction with FIGS. 1A-1B. A non-volatile memory device is a package of one or more dies (or dice). Each die can include two or more planes. For some types of non-volatile memory devices (e.g., NAND devices), each plane includes of a set of physical blocks. In some implementations, each block can include multiple sub-blocks. Each plane carries a matrix of memory cells formed on a silicon wafer and joined by conductors referred to as wordlines (WLs) and bitlines (BLs), such that a wordline joins multiple memory cells forming a row of the matrix of memory cells, while a bitline joins multiple memory cells forming a column of the matrix of memory cells.

Depending on the cell type, each memory cell can store one or more bits of binary information, and has various logic states that correlate to the number of bits being stored. The logic states can be represented by binary values, such as “0 ” and “1,” or combinations of such values, also referred to herein as logical bit values. A memory cell can be programmed (written to) by applying a certain voltage to the memory cell, which results in an electric charge being held by the memory cell, thus allowing modulation of the voltage distributions produced by the memory cell. A set of memory cells referred to as a memory page can be programmed together in a single operation, e.g., by selecting consecutive bitlines. Precisely controlling the amount of the electric charge stored by the memory cell allows establishing multiple logical levels, thus effectively allowing a single memory cell to store multiple bits of information. A read operation can be performed by comparing the measured threshold voltages (Vₜ) exhibited by the memory cell to one or more reference voltage levels in order to distinguish between two logical levels for single-level cell (SLCs) and between multiple logical levels for multi-level cells (MLCs).

In certain memory sub-systems, a controller (e.g., processing device that manages a memory device) performs wear leveling across blocks (including super blocks) of multiples dies of the memory device. Because blocks can reach the point of no longer being able to reliably store data (e.g., due to wear or degradation), the controller can retire one or more blocks in a superblock and replace those block(s) with one or more spare blocks having a similar wear level. If a spare block has a significant program-erase cycle (PEC) gap compared to other blocks in the superblock, the reliability and data integrity may be compromised. To avoid wear level disparity, the controller may perform PEC data cycling by repeatedly causing charge (e.g., in the form of random data patterns) to be moved into and out of memory cells of a spare block to bring the PEC count of the spare block to a level closer to the PEC count of the other blocks of the superblock.

A superblock may be understood as a collection of physical blocks (often one per die or plane arranged in a stripe) that the controller maps to act like a single logical block. When writing to or erasing a superblock, operations are often coordinated across all the blocks in the group, allowing for parallelism and consistent wear-leveling. A superblock typically includes one block per plane (or sometimes per die or per channel). The blocks in a superblock may be of the same physical block index within their respective die or plane (e.g., block of die 0, die 1, etc.). Read, program, and erase operations on a superblock may occur in lockstep for optimization. This enables parallel access across multiple dies or planes to boost throughput.

In the same or other memory sub-systems, the controller may also manage data padding, which is the writing of random data patterns into a remainder of a partially programmed block. Ensuring that data is programmed to memory cells throughout the wordlines of a block may protect data retention by avoiding having empty memory cells adjacent to wordlines associated with programmed memory cells. Data padding can also help from a PEC count perspective within blocks of a superblock.

In both data cycling and data padding, in some memory sub-systems, the controller directs random data patterns to be programmed to each individual page in sequence. Thus, data cycling and padding operations at memory blocks is typically time consuming, as programming each page may employ a full page data load into a page buffer, which is then written to a page of the block, and then a program verify is performed on the programmed data of each page.

In some embodiments, incremental step pulse programming (ISPP) or similar voltage-step based programming may be employed. For example, in ISPP, memory cells are gradually programmed using a sequence of program voltage pulses of increasing magnitude, each followed by a program verify operation to reach a program verify target voltage without grossly exceeding the program verify target voltage. Sensing circuitry within a page buffer may be employed to sense bitlines using the program verify target voltage. This ISPP-based programming may be performed to avoid over-programming and thus stressing the memory cells and/or finishing with overly high threshold voltages. The final threshold voltage levels of the memory cells may be used to determine future read voltage levels for the programmed memory cells. This ISPP-based programming, however, requires a number of time-consuming program verify operations.

Aspects of the present disclosure address the above and other deficiencies associated with time-consuming data cycling and data padding by performing time-saving duplication of a random data pattern within the page buffer and, once programmed to a memory array of the memory device, causing a program verify of just a first page of a wordline group. Once the program verify of the first page is performed, a pulse count for completing the program operation of the first page can be recorded and then used again for programming random data to each subsequent page of that same wordline group (e.g., while skipping program verify of each subsequent page). In some embodiments, in a persistence mode, the same pulse count may also be employed when programming pages associated with the same wordline group but in a different block of the superblock, again without performing a program verify on these pages. Employing the same pulse count is possible because the memory cells associated with the same wordline group is expect to have similar memory cell characteristics, including read voltage value.

In some embodiments, the controller receives an address identifying a portion of the memory array and produces a truncated address by truncating a predefined one or more bits from the address. The portion of the memory array may be a page or multiple pages of data. The truncated address may identify sub-portions of the portion of the memory array. The controller may load a data pattern into a page buffer of the memory device for a first sub-portion of the sub-portions and also cause the memory device to load the data pattern into the page buffer for each additional sub-portion of the sub-portions. The controller may cause the memory device to program the data pattern from the page buffer (which has been duplicated for each sub-portion) into the first sub-portion and into each additional sub-portion of the sub-portions of the memory array. For example, the data pattern that is duplicated within the page buffer may be programmed in parallel into the portion (or page) of the memory array.

In some embodiments, the controller issues, to the memory device, a first program command of a plurality of program commands implementing a data cycling operation at the memory device. The controller can store, to a local memory, a pulse count utilized for writing data to a first page associated with a first wordline of a wordline group (WLG) of the memory device. For example, the pulse count may be recorded or stored upon detecting that a program verify operation has passed (e.g., the page has been programmed to a target program verify voltage). In embodiments, the first page is located at an address of the first program command within a first block. The controller may then load, from the local memory, the pulse count for use in programming each subsequent page associated with the wordline group. In embodiments, truncating the addresses and duplicating random data patterns in the page buffer may be performed along with skipping program verify operations for the majority of the pages of each WLG.

Therefore, advantages of the systems and methods implemented in accordance with some embodiments of the present disclosure include the ability to perform data cycling (e.g., to reduce PEC count disparity between blocks of a memory device) and data padding (e.g., to improve data retention in partially programmed blocks) with significantly lower program times, thus reducing overhead time. Other advantages will be apparent to those skilled in the art of managing data cycling and padding to manage wear level and memory cell characteristics, which will be discussed hereinafter.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such media or memory devices.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1A illustrates one example of a host system 120 coupled to one memory sub-system 110. The host system 120 can provide data to be stored at the memory sub-system 110 and can request data to be retrieved from the memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NOT-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple-level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), NOT-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage a memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

In some embodiments, the memory sub-system 110 includes a memory interface component 113. Memory interface component 113 is responsible for handling interactions of memory sub-system controller 115 with the memory devices of memory sub-system 110, such as memory device 130. For example, memory interface component 113 can send memory access commands corresponding to requests received from host system 120 to memory device 130, such as program commands, read commands, or other commands. In addition, memory interface component 113 can receive data from memory device 130, such as data retrieved in response to a read command or a confirmation that a program command was successfully performed. For example, the memory sub-system controller 115 can include a processor 117 (or processing device) configured to execute instructions stored in local memory 119 for performing the operations described herein.

In at least some embodiments, the memory device 130 includes a program manager 137 configured to carry out memory operations, e.g., in response to receiving memory access commands from the memory interface 113. In some implementations, the local media controller 135 includes at least a portion of the program manager 137 and is configured to perform the functionality described herein. In some implementations, the program manager 137 is implemented on the memory device 130 using firmware, hardware components, or a combination of the above. In some embodiments, control logic of the program manager 137 is integrated in whole or in part within the memory sub-system controller 115 and/or the host system 120. In some embodiments, the memory device 130 includes a page buffer 152, which can be used to program data to the memory cells of the memory device 130 and to read the data out of the memory cells.

FIG. 1B is a simplified block diagram of a first apparatus, in the form of a memory device 130, in communication with a second apparatus, in the form of a memory sub-system controller 115 of a memory sub-system (e.g., the memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), can be a memory controller or other external host device.

The memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bitline). A single access line can be associated with more than one logical row of memory cells and a single data line can be associated with more than one logical column. Memory cells (not shown in FIG. 1B) of at least a portion of the array of memory cells 104 are capable of being programmed to one of at least two target data states.

Row decode circuitry 108 and column decode circuitry 111 are provided to decode address signals. Address signals are received and decoded to access the array of memory cells 104. The memory device 130 also includes input/output (I/O) control circuitry 112 to manage input of commands, addresses and data to the memory device 130 as well as output of data and status information from the memory device 130. An address register 114 is in communication with the I/O control circuitry 112 and row decode circuitry 108 and column decode circuitry 111 to latch the address signals prior to decoding. A command register 124 is in communication with the I/O control circuitry 112 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 111 to control the row decode circuitry 108 and column decode circuitry 111 in response to the addresses.

The local media controller 135 is also in communication with a cache register 118 and a data register 121. The cache register 118 latches data, either incoming or outgoing, as directed by the local media controller 135 to temporarily store data while the array of memory cells 104 is busy writing or reading, respectively, other data. During a program operation (e.g., write operation), data can be passed from the cache register 118 to the data register 121 for transfer to the array of memory cells 104; then new data can be latched in the cache register 118 from the I/O control circuitry 112. During a read operation, data can be passed from the cache register 118 to the I/O control circuitry 112 for output to the memory sub-system controller 115; then new data can be passed from the data register 121 to the cache register 118. The cache register 118 and/or the data register 121 can form (e.g., can form at least a portion of) the page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to the memory sub-system controller 115.

The memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of the memory device 130. In some embodiments, memory device 130 receives command signals (which represent commands), address signals (which represent addresses), and data signals (which represent data) from the memory sub-system controller 115 over a multiplexed input/output (I/O) bus 134 and outputs data to the memory sub-system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) can be used in the various embodiments.

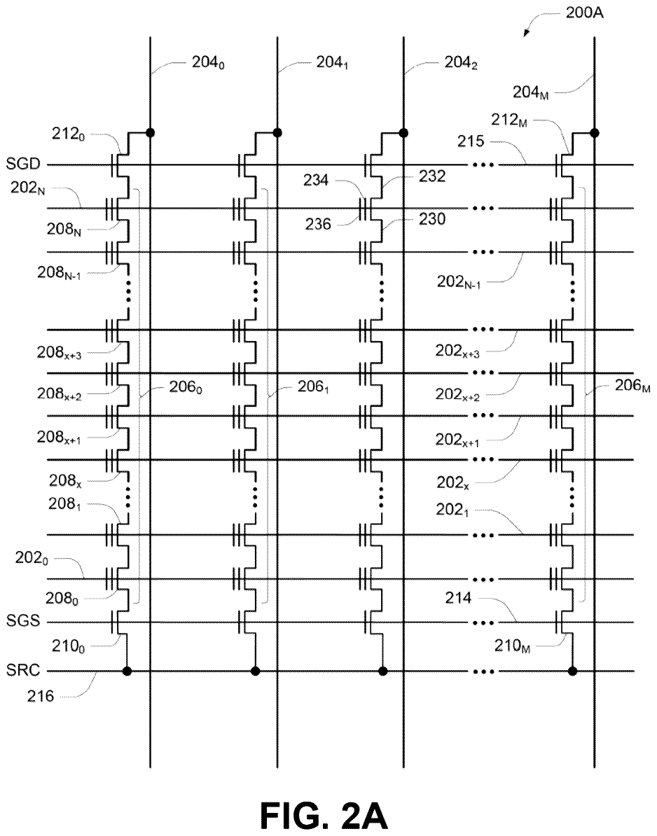

FIG. 2A-2B are schematics of portions of an array of memory cells 200A, such as a NAND memory array, as could be used in a memory of the type described with reference to FIG. 1B according to an embodiment, e.g., as a portion of the array of memory cells 104. Memory array 200A includes access lines, such as wordlines 202₀ to 202_{N}, and data lines, such as bitlines 204₀ to 204_{M}. The wordlines 202 can be connected to global access lines (e.g., global wordlines), not shown in FIG. 2A, in a many-to-one relationship. For some embodiments, memory array 200A can be formed over a semiconductor that, for example, can be conductively doped to have a conductivity type, such as a p-type conductivity, e.g., to form a p-well, or an n-type conductivity, e.g., to form an n-well.

Memory array 200A can be arranged in rows (each corresponding to a wordline 202) and columns (each corresponding to a bitline 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bitline 204 for the corresponding NAND string 206. For example, the drain of select gate 212₀ can be connected to the bitline 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bitline 204. A control gate of each select gate 212 can be connected to select line 215.

The memory array 200A in FIG. 2A can be a quasi-two-dimensional memory array and can have a generally planar structure, e.g., where the common source 216, NAND strings 206 and bitlines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bitlines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bitline 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bitlines 204 (e.g., bitlines 204₀, 204₂, 204₄, etc.) can be one physical page of the memory cells 208 (e.g., even memory cells) while memory cells 208 commonly connected to wordline 202_{N} and selectively connected to odd bitlines 204 (e.g., bitlines 204₁, 204₃, 204₅, etc.) can be another physical page of the memory cells 208 (e.g., odd memory cells).

Although bitlines 204₃-204₅ are not explicitly depicted in FIG. 2A, it is apparent from the figure that the bitlines 204 of the array of memory cells 200A can be numbered consecutively from bitline 204₀ to bitline 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory of the type described with reference to FIG. 1B, e.g., as a portion of the array of memory cells 104. Like numbered elements in FIG. 2B correspond to the description as provided with respect to FIG. 2A. FIG. 2B provides additional detail of one example of a three-dimensional NAND memory array structure. The three-dimensional NAND memory array 200B can incorporate vertical structures which can include semiconductor pillars. The NAND strings 206 can be each selectively connected to a bitline 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bitline 204. Subsets of NAND strings 206 can be connected to their respective bitlines 204 by biasing the select lines 215₀-215_{K} to selectively activate particular select transistors 212 each between a NAND string 206 and a bitline 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each wordline 202 can be connected to multiple rows of memory cells of the memory array 200B. Rows of memory cells that are commonly connected to each other by a particular wordline 202 can collectively be referred to as tiers.

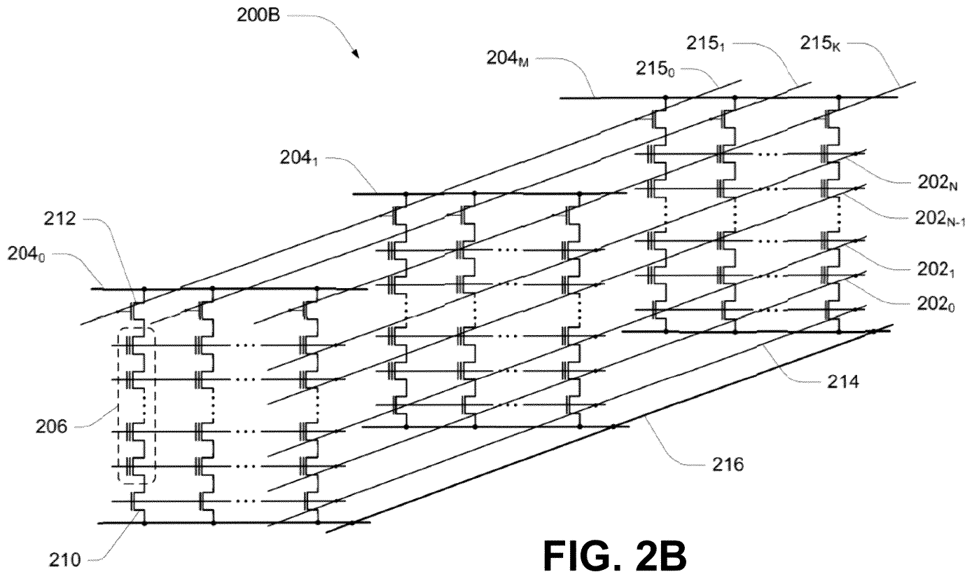

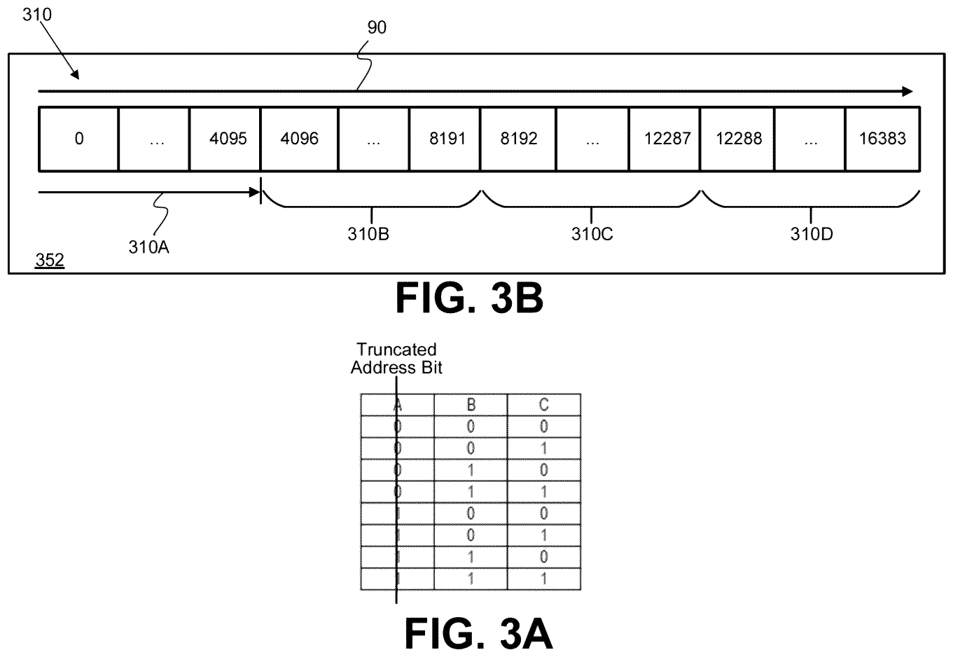

FIG. 3A is a table-based depiction of truncating the most significant bit of addresses of the array of memory cells 104 to provide for more-granular addressing within a portion of the array according to an exemplary embodiment. As illustrated, the addresses include three bits and the most significant bit is truncated to removed from each address. Three bits are illustrated to simplify the example, but as can be appreciated, the address may include a string of bits and the truncated bits can include one or more bits, which may be one or more of the most significant bits. In this way, in varying embodiments, the controller 115 truncates a predefined one or more bits from each address being targeted in a memory array.

FIG. 3B is a block diagram depiction of a page buffer 352 into which is loaded data, which is addressed based on the truncated addressing scheme of FIG. 3A according to some embodiments. In such embodiments, the page buffer 352 is the page buffer 152 illustrated in FIGS. 1A-1B. As illustrated, in advance of performing a data cycling operation, the controller 115 may load a data pattern (e.g., random data) to be programmed to a portion 310 of the memory array 104 (FIG. 1B), thus the portion 310 within the page buffer 352 reflects memory array addressing for ease of explanation. For simplicity, the portion 310 of the memory array 104 illustrates a 16 kilobyte (KB) portion, which can, in some embodiments, correspond to a page of the memory array 104. The data may typically be loaded sequentially into page buffer 352 (e.g., not in parallel), which is illustrated by an arrow 90. Thus, the controller 115 would load the page buffer 152 sequentially from 0 to 16,383 bytes before sending a program command to direct the memory device 130 where to program the loaded data in the memory array 104. Such sequential loading of the data into the entire portion 310 may contribute to a delay before programming each portion (or page) of the memory array 104 being data cycled of padded.

In some embodiments, based on the truncated addressing of FIG. 3A, the controller 115 has reduced (or compressed columns of) the addressing by identifying four sub-portions of the portion 310 of the memory array 104. These sub-portions include a first sub-portion 310A (corresponding to bytes 0-4095) that may still be loaded sequentially. The sub-portions may further include a second sub-portion 310B (corresponding to bytes 4096-8191), a third sub-portion 310C (corresponding to bytes 8192-12287), and a fourth sub-portion 310D (corresponding to bytes 12288-16383). If a sufficient number of bits of each address is truncated, however, there could be 16 sub-portions of 1KB each.

In some embodiments, the controller 115 loads the data pattern (e.g., random data) into each of the sub-portions. The data pattern is sequentially loaded into the first sub-portion 310A in at least some embodiments (indicated by the arrow) during which the data pattern can also be loaded, in parallel, to each of the additional sub-portions, e.g., into the second, third, and fourth sub-portions 310B, 310C, and 310D. In embodiments, the data pattern is duplicated or cloned and simply loaded at the same time into the page buffer 352 for the rest of the sub-portions of the portion 310 of the memory array 104. Loading the duplicated data pattern in parallel into the page buffer 352 for all of the sub-portions significantly reduces the overhead time for loading data and can be done this way because the actual loaded data is unimportant for data cycling and padding so long as the loaded data is somewhat randomized. All of these duplicated data patterns can then be programmed in parallel (e.g., as a page) into the portion 310 of the memory array 104.

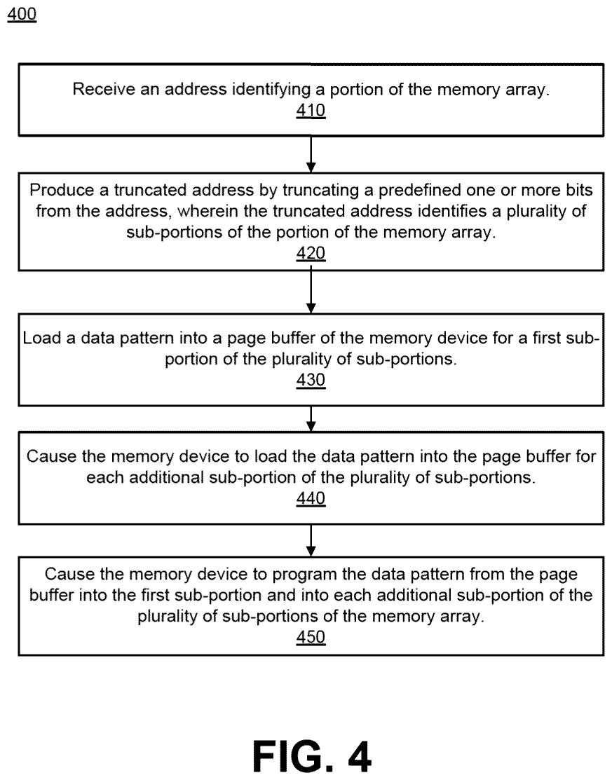

FIG. 4 is a flow diagram of an example method 400 of duplicating a data pattern within a page buffer that is written to sub-portions of the portion of the array of FIG. 3B according to some embodiments. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the memory sub-system controller 115 of FIGS. 1A-1B, e.g., by the processor 117 and/or the memory interface 113 sending random data patterns and program commands to the memory device 130. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 410, the processing logic receives an address identifying a portion of the memory array. This address, for example, may be directed at the beginning of a WLG of a block that is to be data cycled in preparation for being swapped in as a spare block.

At operation 420, the processing logic produces a truncated address by truncating a predefined one or more bits from the address. In embodiments, the truncated address identifies a plurality of sub-portions of the portion of the memory array, as was discussed with reference to FIGS. 3A-3B. For example, producing the truncated address may be performed by truncating the predefined one or more bits from a set of most significant bits of the address.

At operation 430, the processing logic loads a data pattern into a page buffer of the memory device for a first sub-portion of the plurality of sub-portions. For example, the page buffer may be the page buffer 152 or 352 discussed previously.

At operation 440, the processing logic causes the memory device 130 to load the data pattern into the page buffer for each additional sub-portion of the plurality of sub-portions. In some embodiments, loading the data pattern for the first sub-portion (operation 430) is performed concurrently with causing the memory device to load the data pattern into the page buffer for each additional sub-portion of the plurality of sub-portions (operation 440).

At operation 450, the processing logic causes the memory device 130 to program the data pattern from the page buffer into the first sub-portion and into each additional sub-portion of the plurality of sub-portions of the memory array. In some embodiments, causing the memory device to program the data pattern includes issuing a program command associated with a data cycling operation at the memory array 104. The data cycling operation may perform wear-leveling of blocks of a superblock of the memory device 130.

In some embodiments, the memory array 104 includes a plurality of wordlines of a first wordline group, and the address is directed at a first page associated with a first wordline of the plurality of wordlines. Further, the method 400 may be repeated for each page associated with the first wordline, thus saving time in loading random data patterns for each page that is to be programmed in cyclic matter, e.g., PEC data cycling. For example, the processing logic may further receive a second address identifying a second portion of the memory array 104. The processing logic may produce a second truncated address by truncating the predefined one or more bits from the second address. In embodiments, the second truncated address identifies a second plurality of sub-portions of the second portion of the memory array 104. The processing logic may load a second data pattern into a page buffer 352 of the memory device 130 for a first sub-portion of the second plurality of sub-portions. The processing logic may cause the memory device 130 to load the second data pattern into the page buffer for each additional sub-portion of the second plurality of sub-portions. The processing logic may cause the memory device 130 to program the second data pattern from the page buffer 352 into the first sub-portion and into each additional sub-portion of the second plurality of sub-portions of the memory array 104.

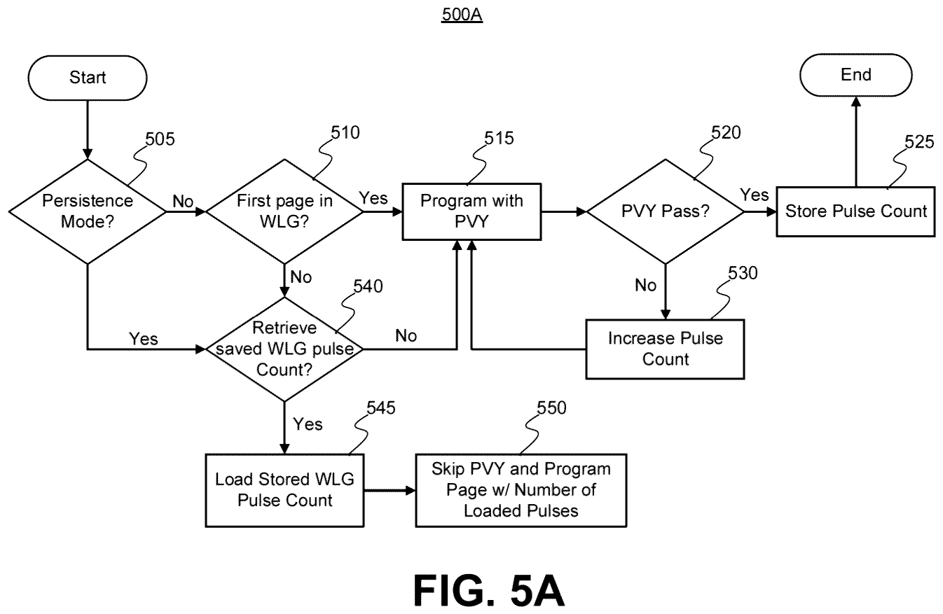

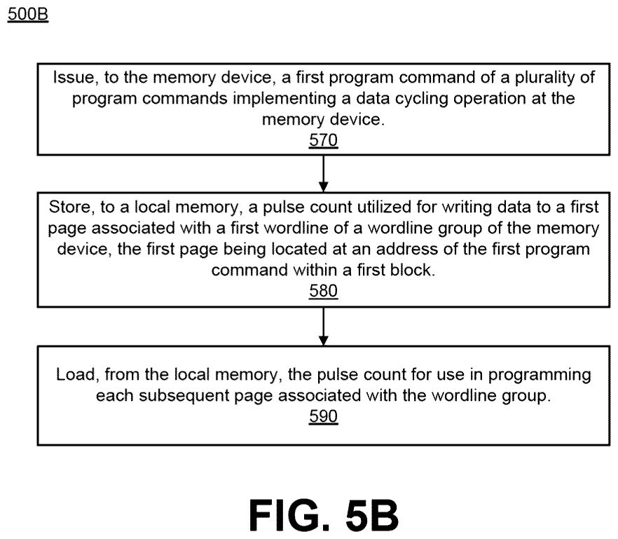

FIG. 5A is a flow diagram of an example method 500A of cycling or padding data using a pulse count determined from programming a first page of a wordline group (WLG) according to some embodiments. The method 500A can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500A is performed by the memory sub-system controller 115 of FIGS. 1A-1B, e.g., by the processor 117 and/or the memory interface 113 sending random data patterns and program commands to the memory device 130. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 505, the processing logic determines whether a persistence mode is enabled. Persistence mode may be understood as a mode in which a pulse count used for programming pages of memory cells associated with a WLG at one block can also be used for programming pages of memory cells associated with that same WLG at a subsequent block of a superblock, which at times herein, is referred to as a second block.

If the answer at operation 505 is no, the processing logic, at operation 510, determines whether the page being programmed is the first page in the WLG.

If the answer at operation 510 is yes, the processing logic, at operation 515, causes a program operation with a program verify be performed to program the first page.

At operation 520, the processing logic determines whether the program verify has passed, e.g., whether a threshold voltage of the page being programmed has satisfied a target program verify voltage within memory cells of the first page. If the answer is no at operation 520, the processing logic, at operation 530, increases the pulse count and continues to program the first page (e.g., at operation 515) using incremental step pulse programming (ISPP) or similar voltage-step based programming. For example, in ISPP, memory cells are gradually programmed using a sequence of program voltage pulses of increasing magnitude, each followed by a verify operation. This ISPP-based programming may be performed to avoid over-programming and thus stressing the memory cells and/or finishing with overly high threshold voltages.

If the answer is yes at operation 520, the processing logic, at operation 525, stores the pulse count as the number of program pulses employed to program the first page. For example, the number of program voltage pulses used to program the first page using ISPP may be stored in, for example, the local memory 119 or other system memory.

If the answer is no at operation 510 or yes at operation 505, the processing logic, at operation 540, determines whether a pulse count for the current WLG has been retrieved. If the answer is no, the method 500A loops back through operation 515 to perform a program operation with a program verify on the current page being programmed. This may be necessary, for example, after a reboot and the pulse count stored in the local memory 119 lost.

If the answer is yes at operation 540, the processing logic, at operation 545, loads the stored pulse count, e.g., from the local memory 119.

At operation 550, the processing logic programs the page (which is presumed to be a subsequent page of the WLG) using the loaded pulse count and without use of program verify. In this way, each subsequent page of the WLG other than the first page may be programmed using the loaded pulse count and skipping performing the program verify, saving significant operational overhead. This type of shortcut to programming can be performed because memory cells within the same WLG can be assumed to have similar characteristics, including PEC count. Also, the movement of charge into the memory cells is sufficient to perform PEC-based cycling or data padding, as the random data patterns used are not expected to be read out later (e.g., is not user data that will be accessed for applications or system operation or the like).

FIG. 5B is a flow diagram of an example method 500B of cycling or padding data using a pulse count determined from programming the first page of the WLG according to at least some embodiments. The method 500B can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500B is performed by the memory sub-system controller 115 of FIGS. 1A-1B, e.g., by the processor 117 and/or the memory interface 113 sending random data patterns and program commands to the memory device 130. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 570, the processing logic issues, to the memory device 130, a first program command of a plurality of program commands implementing a data cycling operation at the memory device.

At operation 580, the processing logic stores, to the local memory, a pulse count utilized for writing data to a first page associated with a first wordline of a wordline group of the memory device, the first page being located at an address of the first program command within a first block. In some embodiments, the first program command includes a program verify operation, where the pulse count is associated with satisfying a target program verify voltage within memory cells of the first page, e.g., during ISPP-based programming.

At operation 590, the processing logic loads, from the local memory, the pulse count for use in programming each subsequent page associated with the wordline group. For example, for each subsequent page associated with the wordline group, the processing logic may cause data to be written to the subsequent page using a number of program pulses corresponding to the pulse count and without performing a program verify operation. The data may be the random data pattern referred to earlier for performing the data cycling or data padding operations.

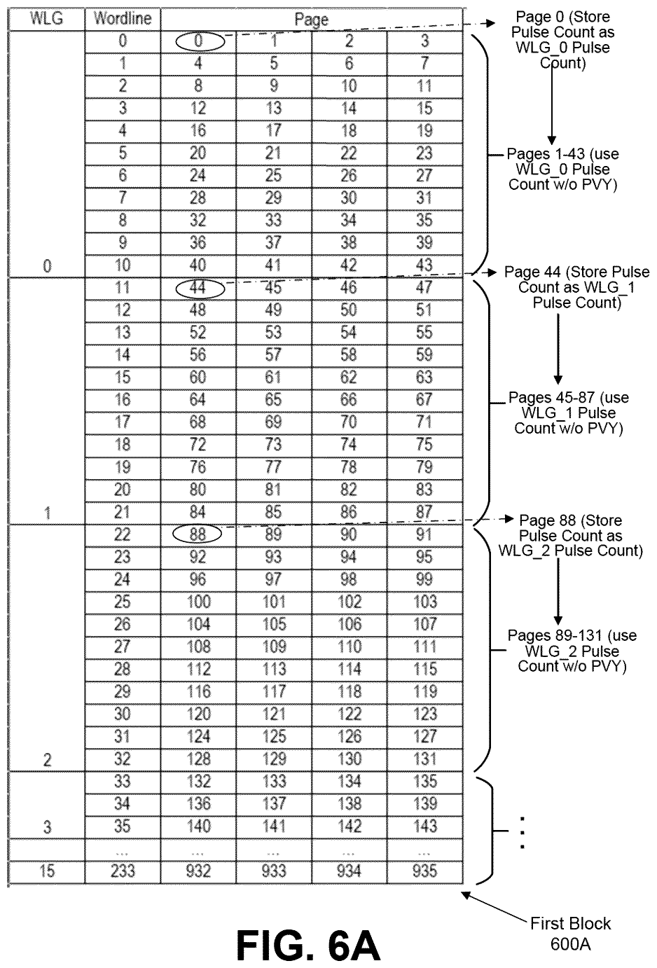

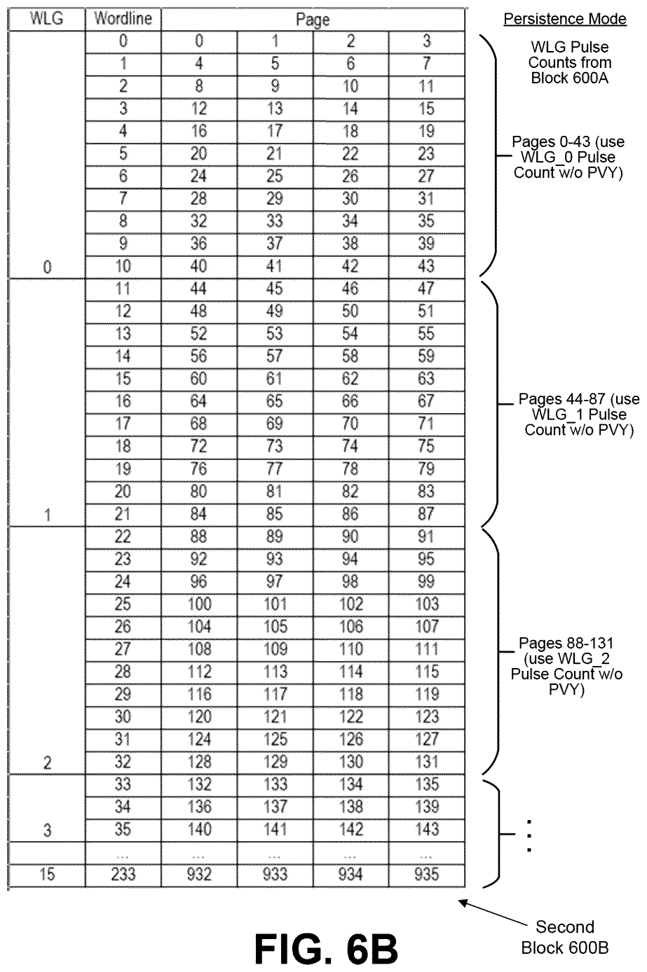

FIG. 6A is a memory array-based depiction of the methods of FIGS. 4-5B performed across multiple WLGs of a first block 600A according to some embodiments. For example, FIG. 6A illustrates a portion of a block of memory within the memory array 104 of the memory device 130. As each page is programmed, the method 400 can be performed to duplicate a random data pattern into the page buffer 352 and program the duplicated random data patterns from the page buffer 352 into the memory array 104. Further, the page count for programming the first page of each wordline group (WLG) can be determined based on a program verify operation such as at operations 515 and 520 of FIG. 5A. This page count can be stored in the local memory 119 or other system-based memory and then loaded for use in programming each subsequent page, for instance, to program pages 1-43 of WLG_0.

Continuing on through the rest of the first block 600A, a second page count can be determined upon programming, with a program verify, the first page (or page 44) of WLG_1. This second page count can be stored and then loaded for programming each additional page, e.g., pages 45-87 of WLG_1. Further, a third page count can be determined upon programming, with a program verify, the first page (or page 88) of WLG_2. This third page count can be stored and then loaded for programming each additional page, e.g., pages 89-131 of WLG_2.

FIG. 6B is a memory array-based depiction of employing the persistence mode of FIG. 5A across multiple WLGs of a second block 600B according to some embodiments. For example, as discussed with reference to operation 505 of FIG. 5A, the processing logic may detect that the persistence mode has been enabled. In such an embodiment, the processing logic loads the pulse count from the local memory 119, the pulse count being associated with the first wordline group (WLG_0) and the first block 600A (e.g., where the first block 600A and the second block 600B can be blocks within the same superblock). The processing logic may cause the memory device 130 to write data (e.g., which can be random data) to each page of the second block 600B using the loaded pulse count. In this way, because the second block 600B shares the first wordline group with the first block 600A, the loaded pulse count associated with WLG_0 can be used on each page of the WLG_0 while skipping the program verify operation.

In embodiments, the processing logic follows a similar pattern for each subsequent wordline group. For example, for programing the second wordline group (WLG_1), the processing logic may load the second stored pulse count for WLG_1 from the first block 600A and use this loaded second pulse count for programming each page of the WLG_1. Further, for programing the third wordline group (WLG_2), the processing logic may load the third stored pulse count from the first block 600A and us this loaded third pulse count for programming each page of the WLG_2.

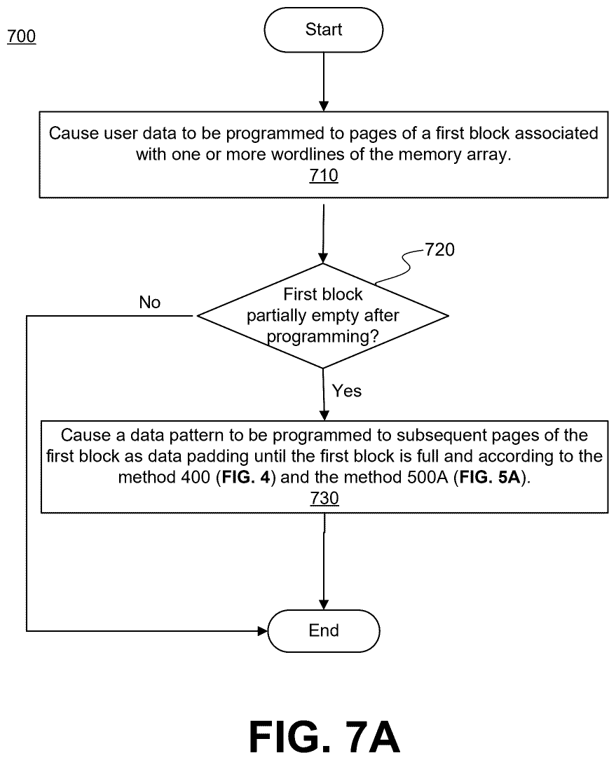

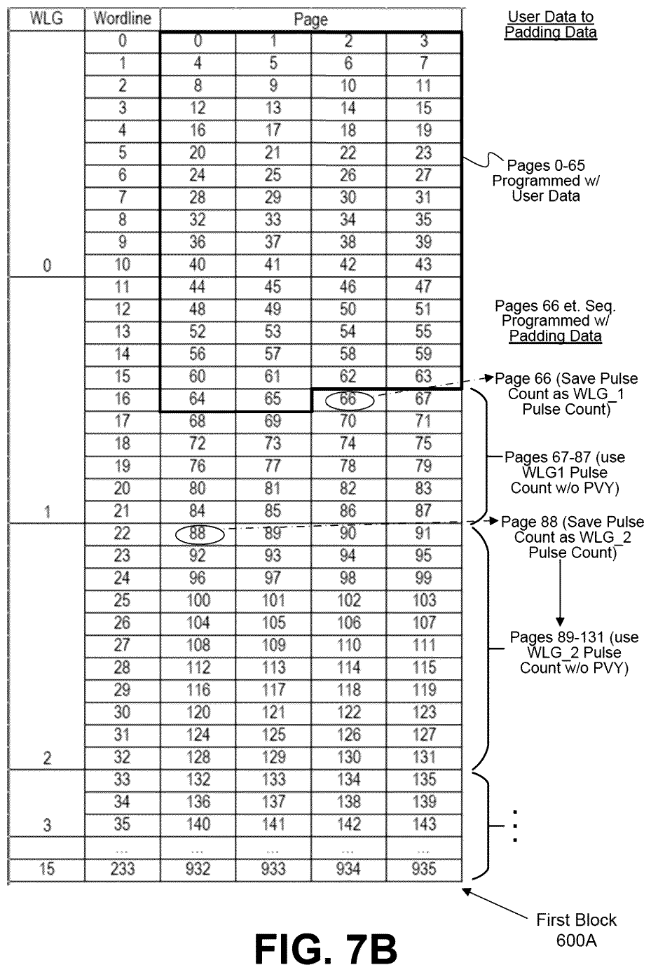

FIG. 7A is a flow chart of a method 700 for padding pages of an incompletely programmed block with a random data pattern according to some embodiments. FIG. 7B is a memory array-based depiction of employing the method 700 of FIG. 7A in padding data after user data partially fills a block according to an exemplary embodiment. The method 700 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 700 is performed by the memory sub-system controller 115 of FIGS. 1A-1B, e.g., by the processor 117 and/or the memory interface 113 sending random data patterns and program commands to the memory device 130. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 710, the processing logic causes user data to be programmed to pages of the first block 600A associated with one or more wordlines of the memory array. For example, the user data may be programmed to pages 0-43 of the first wordline group (WLG_0) and to pages 44-65 of the second wordline group (WLG_1), as illustrated in FIG. 7B.

At operation 720, the processing logic determines whether the first block 600A is left partially empty at the end of programming. For example, the end of programming may be signaled by closing further programming to the first block 600A due to passage of time and/or increase in temperature, thus in consideration of threshold read voltages of the first block 600A remaining consistent throughout the user data pages. If the user data has completely filled the first block 600A at the end of programming, the method 700 may end.

In response to detecting, at operation 720, the first block 600A is left partially empty, the processing logic, at operation 730, causes a data pattern to be programmed to subsequent pages of the first block 600A as data padding until the first block 600A is full. In some embodiments, the data padding programming to the subsequent empty pages of the first block 600A is performed as was discussed with reference to the method 400 of FIG. 4 and the method of FIG. 5A, e.g., starting with, at operation 410, receiving an address identifying a first page to padded in the first block 600A and continuing on through operation 450 and the operations of FIG. 5A, as will be discussed.

In some embodiments, causing the memory device 130 to program the data pattern includes issuing a program command associated with a data cycling operation at the memory array 104, e.g., where the program command is directed starting at empty page 66 of WLG_1 (FIG. 7B). In embodiments, the memory array 104 includes a plurality of wordlines of the second wordline group (WLG_1), where page 66 is associated with a wordline of the plurality of wordlines, e.g., a sixth wordline of WLG_1. In some embodiments, the processing logic further issues a plurality of subsequent programs commands to the memory device, each subsequent programming command to cause the memory device to write the data pattern or another data pattern into each of a plurality of sub-portions of each subsequent page of the first block. For example, these pages may span from page 67 through the remainder of the first block 600A.

With additional reference to operations 515-525 FIG. 5A, the processing logic causes the memory device 130 to perform a program verify associated with writing the data pattern to the page 66 of the first block 600A and storing, to the local memory 119, a pulse count utilized for writing the data pattern to page 66 and to satisfy a target program verify voltage within memory cells of page 66. Further, for each subsequent page of the second wordline group (WLG_1) of the first block, the processing logic may load the pulse count from the local memory 119 and cause the memory device 130 to write the data pattern or a second data pattern to the subsequent page using the loaded pulse count.

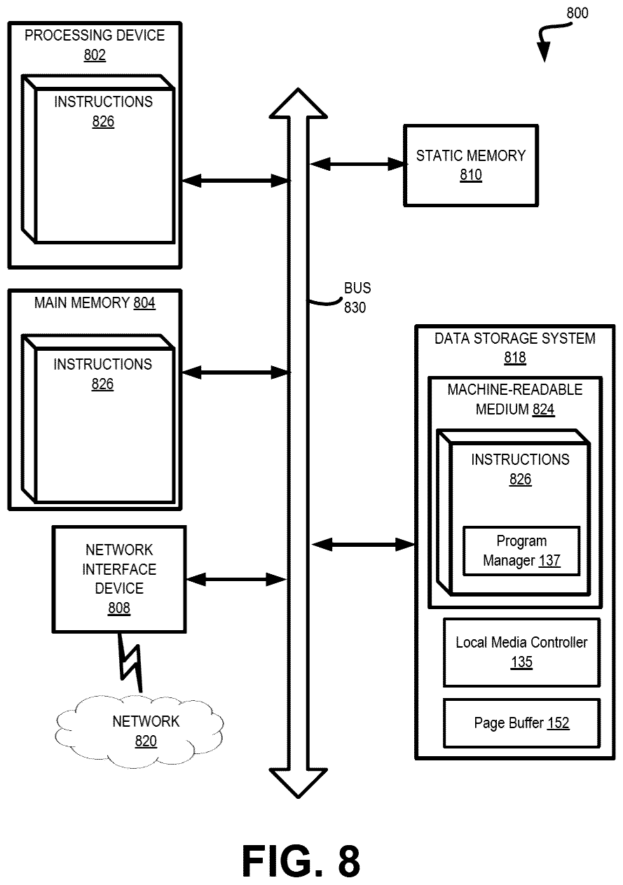

FIG. 8 illustrates an example machine of a computer system 800 within which a set of instructions, for causing the machine to perform any one or more of the methodologies discussed herein, can be executed. In some embodiments, the computer system 800 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the memory sub-system controller 115 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM) or Rambus DRAM (RDRAM), etc.), a static memory 810 (e.g., flash memory, static random access memory (SRAM), etc.), and a data storage system 818, which communicate with each other via a bus 830.

Processing device 802 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 can also be one or more special-purpose processing devices such as an application specific integrated circuit (ASIC), a field programmable gate array (FPGA), a digital signal processor (DSP), network processor, or the like. The processing device 802 is configured to execute instructions 828 for performing the operations and steps discussed herein. The computer system 800 can further include a network interface device 812 to communicate over the network 820.

The data storage system 818 can include a machine-readable storage medium 824 (also known as a non-transitory computer-readable storage medium) on which is stored one or more sets of instructions 826 or software embodying any one or more of the methodologies or functions described herein, including those associated with the program manager 137. The data storage system 818 can further include the local media controller 135 and the page buffer 152 that were previously discussed. The instructions 828 can also reside, completely or at least partially, within the main memory 804 and/or within the processing device 802 during execution thereof by the computer system 800, the main memory 804 and the processing device 802 also constituting machine-readable storage media. The machine-readable storage medium 824, data storage system 818, and/or main memory 804 can correspond to the memory sub-system 110 of FIG. 1A.

In some embodiments, the instructions 826 include instructions to implement functionality corresponding to a controller (e.g., the memory sub-system controller 115 of FIG. 1A). While the machine-readable storage medium 824 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device comprising a memory array; and
a processing device coupled to the memory device, the processing device to perform operations comprising:
receiving an address identifying a portion of the memory array;
producing a truncated address by truncating a predefined one or more bits from the address, wherein the truncated address identifies a plurality of sub-portions of the portion of the memory array;
loading a data pattern into a page buffer of the memory device for a first sub-portion of the plurality of sub-portions;
causing the memory device to load the data pattern into the page buffer for each additional sub-portion of the plurality of sub-portions; and
causing the memory device to program the data pattern from the page buffer into the first sub-portion and into each additional sub-portion of the plurality of sub-portions of the memory array.

2. The system of claim 1, wherein causing the memory device to program the data pattern comprises issuing a program command associated with a data cycling operation at the memory array, and wherein the data cycling operation is to perform wear-leveling of blocks of a superblock of the memory device.

3. The system of claim 1, wherein the loading the data pattern for the first sub-portion is performed concurrently with causing the memory device to load the data pattern into the page buffer for each additional sub-portion of the plurality of sub-portions.

4. The system of claim 1, wherein the producing the truncated address is performed by truncating the predefined one or more bits from a set of most significant bits of the address.

5. The system of claim 1, wherein the memory array comprises a plurality of wordlines of a first wordline group, and the address is directed at a first page associated with a first wordline of the plurality of wordlines.

6. The system of claim 5, wherein the operations further comprise:
causing the memory device to perform a program verify associated with writing the data pattern to the first page of a first block; and
storing, to a local memory, a pulse count utilized for writing the data pattern to the first page and to satisfy a target program verify voltage within memory cells of the first page.

7. The system of claim 6, wherein the operations further comprise, for each subsequent page of the first wordline group of the first block:
loading the pulse count from the local memory; and
causing, using the loaded pulse count, the memory device to write the data pattern or a second data pattern to the subsequent page.

8. The system of claim 6, wherein the operations further comprise, for writing to each subsequent page of the first wordline group at a second block:
detecting that a persistence mode is enabled;
loading the pulse count from the local memory, the pulse count being associated with the first wordline group and the first block; and
causing the memory device to write the data pattern or a second data pattern to the subsequent page of the second block using the loaded pulse count.

9. A system comprising:
a memory device; and
a processing device coupled to the memory device, the processing device to perform operations comprising:
issuing, to the memory device, a first program command of a plurality of program commands implementing a data cycling operation at the memory device;
storing, to a local memory, a pulse count utilized for writing data to a first page associated with a first wordline of a wordline group of the memory device, the first page being located at an address of the first program command within a first block; and
loading, from the local memory, the pulse count for use in programming each subsequent page associated with the wordline group.

10. The system of claim 9, wherein the first program command includes a program verify operation, and wherein the pulse count is associated with satisfying a target program verify voltage within memory cells of the first page.

11. The system of claim 9, wherein the operations further comprise, for each subsequent page associated with the wordline group, causing data to be written to the subsequent page using a number of program pulses corresponding to the pulse count and without performing a program verify operation.

12. The system of claim 9, wherein the operations further comprise, for writing to each second page of the wordline group at a second block:
detecting that a persistence mode is enabled;
loading the pulse count from the local memory, the pulse count being associated with the wordline group and the first block; and
causing the memory device to write data to the second page of the second block using the loaded pulse count.

13. The system of claim 9, wherein the operations further comprise:
receiving an address identifying the first page;
producing a truncated address by truncating a predefined one or more bits from the address, wherein the truncated address identifies a plurality of sub-portions of the first page;
loading a data pattern into a page buffer of the memory device for a first sub-portion of the plurality of sub-portions;
causing the memory device to load the data pattern into the page buffer for each additional sub-portion of the plurality of sub-portions; and
causing the memory device to program the data pattern from the page buffer into the first sub-portion and into each additional sub-portion of the plurality of sub-portions of the page.

14. The system of claim 13, wherein causing the memory device to program the data pattern comprises issuing a program command associated with the data cycling operation, and wherein the data cycling operation is to perform wear-leveling of blocks of a superblock of the memory device.

15. The system of claim 13, wherein at least one of:
the loading the data pattern for the first sub-portion is performed concurrently with causing the memory device to load the data pattern into the page buffer for each additional sub-portion of the plurality of sub-portions; or
the producing the truncated address is performed by truncating the predefined one or more bits from a set of most significant bits of the address.

16. A method comprising:
causing, by a processing device coupled with a memory device having a memory array, user data to be programmed to pages of a first block associated with one or more wordlines of the memory array; and
in response to detecting the first block is left partially empty, causing a data pattern to be programmed to subsequent pages of the first block as data padding until the first block is full, wherein causing the data pattern to be programmed comprises:
receiving an address identifying a first page to be padded in the first block;
producing a truncated address by truncating a predefined one or more bits from the address, wherein the truncated address identifies a plurality of sub-portions of the first page;
loading the data pattern into a page buffer of the memory device for a first sub-portion of the first page;
causing the memory device to load the data pattern into the page buffer for each additional sub-portion of the page; and
causing the memory device to program the data pattern from the page buffer into the first sub-portion and into each additional sub-portion of the first page.

17. The method of claim 16, wherein causing the memory device to program the data pattern comprises issuing a program command associated with a data cycling operation at the memory array, wherein the memory array comprises a plurality of wordlines of a first wordline group, the first page being associated with a first wordline of the plurality of wordlines, and the method further comprising issuing a plurality of subsequent programs commands to the memory device, each subsequent programming command to cause the memory device to write another the data pattern or another data pattern into each of a plurality of sub-portions of each subsequent page of the first block.

18. The method of claim 17, wherein the method further comprise:
causing the memory device to perform a program verify associated with writing the data pattern to the first page of the first block; and
storing, to local memory, a pulse count utilized for writing the data pattern to the first page and to satisfy a target program verify voltage within memory cells of the first page.

19. The method of claim 18, wherein the method further comprises, for each subsequent page of the first wordline group of the first block:
loading the pulse count from the local memory; and
causing the memory device to write the data pattern or a second data pattern to the subsequent page using the loaded pulse count.

20. The method of claim 18, wherein the method further comprises, for writing to each second page of the first wordline group at a second block:
detecting that a persistence mode is enabled;
loading the pulse count from the local memory, the pulse count being associated with the first wordline group and the first block; and
causing the memory device to write the data pattern or a second data pattern to the second page of the second block using the loaded pulse count.
